(19) United States
(12) Patent Application Publication
(10) Pub. No.: US 2004/0101785 A1
(43) Pub. Date: May 27, 2004

(54) Process of improved grayscale lithography

(76) Inventors: David R. Brown, Meridinville, AL (US); Peter Erbach, Huntsville, AL (US); Bob Elliot, Madison, AL (US)

Correspondence Address: Patent Administrator, Mems Optical, Inc., 205 Import Circle, Suite 2, Huntsville, AL, 35806, US

(21) Appl. No.: 10/300,865

(22) Filed: Nov. 21, 2002

(51) Int. Cl. G02B 5/30; G03C 5/00; G03F 9/00; G02B 27/28

(52) U.S. Cl. 430/321; 430/322; 359/485

(57) ABSTRACT

Methods and apparatuses for minimizing the errors associated with substrate etching are presented. The methods and apparatuses use intentional defocusing of the pattern image on the photoresist to minimize errors in the etching process particularly grayscale etching and multiple exposure contributions from neighboring patterns.

### BACKGROUND OF THE INVENTION

1. Field of the Invention

The present invention relates to Grayscale photolithography. More particularly it relates to using various focusing techniques to improve grayscale etch uniformity.

2. Description of Related Art

Grayscale photolithography has revolutionized the way curved surfaces are etched into substrates. In grayscale photolithography, grayscale masks are used to etch smooth surfaces into substrates. The smooth surfaces etched enable the creation of various shapes and curves, symmetric and asymmetric, lending themselves well for the use in fabrication of micro-optical systems. The quality of these surfaces are dependent on the qualities of etching which in turn depend, at least partly, on the qualities of the grayscale mask. Hence, errors in the grayscale mask can result in errors in the etched surfaces.

The use of grayscale etching in the formation of microlenses is typified in co-pending application “Deep Grayscale Etching of Silicon” (PCT/US01/42629) to Whitley et al. herein incorporated by reference. A light (usually UV) from an illumination device (e.g. a stepper) illuminates a grayscale mask, forming a pattern image on a photoresist layer, which selectively exposes the photoresist layer such that the pattern image, or its negative, is later developed in the photoresist layer. After development, the pattern image in the photoresist is used to etch a pattern in the substrate. Significant errors in the resultant patterned substrate surface are often due to writing errors in the grayscale mask.

There are several methods of producing a grayscale mask but most use an electron beam or laser beam to write the mask from a chrome base. Etched substrates are susceptible to three types of errors: the first error has to do with the roughness of the surface of the photoresist layer; the second error has to do with positioning errors of the mask writing tool (i.e. stitching error); and the third error is due to non-uniformity in wafer etching. The writing of the mask is susceptible to the first two errors typically plaguing etched substrates.

The first source of error arises from general roughness in the surface of the photosensitive material. This error can be caused by the slight variations in the dose of the writing tool, usually an electron beam (e-beam) or laser. In the case of the half tone process, the chosen pixel shape scheme can cause this error. The period of irregularity caused by this general roughness error is typically on the order of 10 microns.

The second source of error is a stitching error; it is geometric and is induced by slight variations in the positioning and size of the writing tool. Stitching error is due to slight inaccuracies of the stage and field of the writing tool. The stage of the writing tool refers to the horizontal sweep, wherein slight variation in the positioning of the horizontal line results in stitching error. The field refers to the width of the writing line, wherein variation in the width of the writing line also results in stitching error. The stitching error has a low frequency period and manifests itself in slight vertical lines on the etched surface.

The third error forms inconsistencies between multiple lenses in an array of lenses on a wafer. This is caused by subtle variations across the mask, which are caused by slight “wafer” level variational processes such as development or chrome etch processes. High quality lens typically require <1% non-uniformity in the focal length across the large array of mass produced lenses.

The three errors are cumulative and add to degrade lens quality and reproducibility. FIG. 1 illustrates the first two errors on an actual lens etched by grayscale etching of a substrate using the standard procedure of focusing the pattern image at the photoresist layer. Stitch errors 10 are evident and shown as straight lines in the lens surface. Surface roughness errors 20 are also evident and are shown as high frequency rings in the lens surface. The lens shown in FIG. 1 has a height of 17.5 microns, a peak to valley roughness (difference) of ˜216 nm or 1.2% of total height, and a root mean squared (RMS) roughness of ˜44 nm or 0.2% of the total height.

Standard practice focuses the pattern image from the mask on the photoresist layer. FIG. 2 illustrates a standard arrangement for developing and patterning a photoresist layer 150. A stepper 110 emits focusing light, defined by conical extent 120. The pattern image is focused at a plane 140 on or in the photoresist layer 150, which is deposited upon the substrate 160. The photoresist 150 is patterned through exposure by the illumination light 120 passing through the grayscale mask 130 and is then developed. The mask (in the present example, the grayscale mask) can contain errors addressed by the present invention. The mask 130 contains a pattern that is imparted to the light passing through the mask 130, creating a pattern image 105. The pattern image 105 is reduced to form a reduced image 107 that is focused on the photoresist 150. Typically, the image is focused on the top of the photoresist layer. The reduced image 107 exposes and patterns the photoresist 150 which can then be used to obtain the desired etch pattern in substrate 160 upon etching.

A method for minimizing the three mentioned errors is important for developing high quality, reproducible lenses.

### SUMMARY OF THE INVENTION

It is therefore an object of the present invention to provide a method and apparatus to reduce errors associated with substrate etching. It is further an object of the present invention to provide a method and apparatus to reduce errors associated with microlens fabrication using grayscale etching.

These and other objects of the present invention can be realized by the methods/devices of intentionally defocusing the pattern image produced on the photoresist layer. A first method involves intentionally setting the stepper to focus the pattern image at a point other than the optimal focus setting (at the photoresist surface). A second and third method modifies the stepper so that the stepper is out of focus for its entire design range by physically moving the stepper and/or by using optical devices. A fourth method places a thin clear cover plate on top of the photoresist-covered wafer providing defocusing of the incident illumination, and a fifth method exposes identical patterns on a mask to obtain an average image of the pattern on the photoresist reducing errors. The methods discussed can be used in combination.

The first method uses an intentional defocusing setting of the stepper. If more defocus is needed the second method moves the stepper a distance greater than the stepper's defocus range. To allow a return to standard focusing, an optical device can be added to modify the focusing characteristics of the illuminating light emitted from the moved stepper, resulting in a change in the focusing characteristics of the pattern image.

If a method is needed to defocus beyond the built in range of defocus and still allow focusing when needed, as mentioned above, this can be accomplished by adding optical devices and elements. The third method places an optical device between the stepper and the mask so as to alter the focusing characteristics of the pattern image. An optical device can also allow normal focusing in addition to the intentional defocusing.

The fourth method places an optical device between the mask and photoresist layer. A cover plate can be used with a standard stepper, or in addition to another optical device placed between the stepper and the mask.

A fifth method multiple exposes identical patterns on a mask, resulting in an averaged image of the identical pattern in a photoresist, deposited on a substrate, reducing errors, associated with variability across the mask, in the developed photoresist.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the following detailed description given hereinbelow and the accompanying drawings which are given by way of illustration only, and thus do not limit the present invention, and wherein:

FIG. 1 is an illustration of a computer display showing typical errors in an etched micro-lens;

FIG. 2 is an illustration showing a standard focus of a pattern image at a photoresist layer;

FIG. 3 is an illustration showing the intentional defocusing of a pattern image at a photoresist layer;

FIG. 4 is an illustration showing the intentional defocusing of a pattern image at a photoresist layer by using an optical device;

FIG. 5 is an illustration showing the intentional defocusing of a pattern image at a photoresist layer by using a cover plate;

FIG. 6 is an illustration showing the intentional defocusing of a pattern image at a photoresist layer by using a cover plate and an optical device;

FIG. 7 is an illustration of a computer display showing the effect on typical errors using an embodiment of the present invention to intentionally defocus the illumination; and

FIG. 8 illustrates the use of multiple exposures of patterns on a mask to form an image in a photoresist layer, where the image is the result of the combined exposures using multiple patterns, and the resultant image developed in the photoresist has decreased fabrication errors and forms one element of an array of images form by the same method, the resultant array having decreased fabrication errors, of the type discussed above.

### DESCRIPTION OF PREFERRED EMBODIMENTS

As noted above there are essentially three types of errors associated with quality micro-lens production. Defocusing the pattern image formed on the surface of the photoresist layer can minimize errors associated with etching of micro-lens is addressed in the embodiment of the present invention. Like figures on the appended drawings refer to like elements in the appended figures.

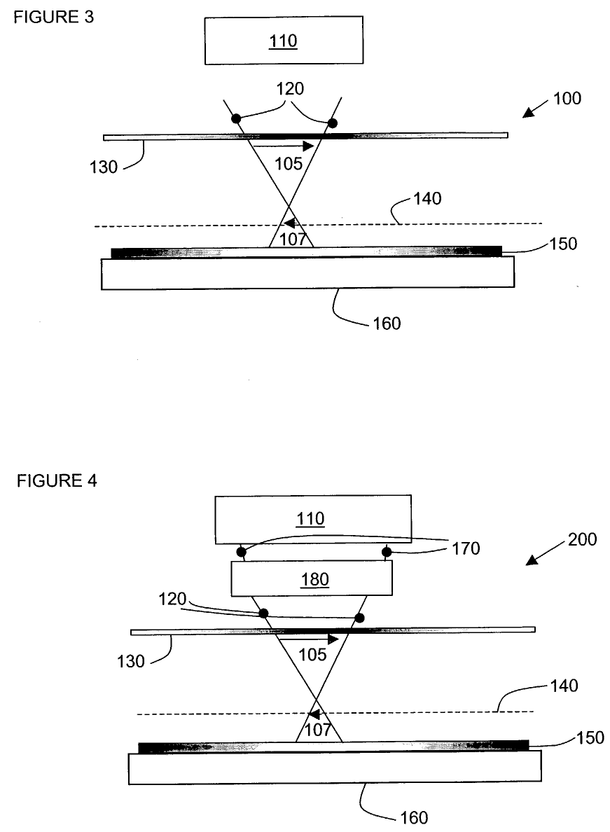

In accordance with the present invention, a first method of minimizing errors, associated with substrate etching, intentionally defocuses the pattern image illuminating the photoresist layer(s) by adjusting the focusing control on the stepper 110 a shown in FIG. 3. Many steppers have a focusing range used to accurately focus the pattern image 107 on the photoresist layer 150 in accordance with standard practice where the position of the stepper is referred to as the focused position of the stepper. Some steppers will allow up to approximately 50 microns of defocus and others only a few microns of defocus. For some applications and masks 50 microns may be enough. Thus, the first method intentionally defocuses the pattern image away from the photoresist layer, an amount greater than would normally occur through erroneous focusing. As discussed above the standard practice is to focus the pattern image on or in the photoresist layer. Erroneous, unintentional, defocusing can result in focusing of the pattern image away from the photoresist layer but within a few microns of the optimum focusing point, which is predetermined to lie within or on the photoresist layer. The intentional defocusing of the pattern image according to the first method defocuses the pattern image tens of microns or more away from the optimum focus point on or in the photoresist layer. The intentional defocusing smoothes out the illumination intensity, decreasing errors associated with stitching, surface roughness, and non-uniform etching of the substrate.

FIG. 3 illustrates a device/mask 100 using the first method according to the present invention. A stepper 110 emits focusing light, defined by conical extent 120. A pattern image 107 is focused at a plane 140 above the photoresist layer 150. Focus at plane 140 results in a defocus of the pattern image on the photoresist layer 150, deposited upon the substrate 160. The pattern image 107, focused on plane 140, is shown above the photoresist layer 150 but can also be below the photoresist layer. The photoresist 150 is patterned and developed by the illumination light 120 passing through the grayscale mask 130 and it is the mask (in the present example the grayscale mask) that can contain the errors seeking to be addressed by the present invention.

The mask 130 contains a pattern that is imparted to the light passing through the mask 130, creating a pattern image 105. The pattern image 105 is reduced to form a reduced image 107 that is focused on the plane 140 that does not lie on or in the photoresist layer 150 forming a defocused pattern image on the photoresist layer 150. The defocused pattern image 107 exposes the photoresist 150 forming a deformed pattern in the photoresist, which can be used to obtain the desired etch pattern in substrate 160 upon etching. Intentionally defocusing the pattern image on the photoresist smoothes the errors associated with substrate etching.

The term “grayscale mask” as used herein may be any suitable mask, for example, a binary grayscale mask as disclosed in U.S. Pat. No. 5,310,623 to Gal, a HEBs glass grayscale mask or any other mask suitable for continuous variation in exposure of the photoresist facilitating etching of variable contours in a plane perpendicular to the surface of the substrate. The discussion herein should not be interpreted to limit the mask to a grayscale mask nor should the errors mentioned above be interpreted to be the only errors on the mask or in the etching process that can be addressed by the present invention.

There are situations when the intentional defocus must be beyond the focusing range built into a particular stepper. To obtain additional range for defocusing, the stepper itself can be physically moved or equivalently optically adjusted. Optical adjustment allows the user to revert back to standard focusing procedures when desired. To optically adjust the stepper's focusing range or point, lenses can be used before the light illuminates a mask. FIG. 4 illustrates a device 200 using an embodiment of the present invention having an optical device 180, provided between the stepper 110 and mask 150, to varying the focusing characteristics of the light emitted from the stepper 110. Light, defined by the conical extents 170, is emitted from the stepper 110 and is incident upon an optical device 180. The optical device 180 changes the focusing characteristics of the incident light. The transmitted light, defined by the conical extents 120, passes through a mask 130. The mask 130 contains a pattern that is imparted to the light passing through the mask 130, creating a pattern image 105. The pattern image 105 is reduced to form a reduced image 107 that is focused on the plane 140 spaced away from the photoresist layer 150, forming a defocused pattern image on the photoresist layer 150. The defocused pattern image, patterns and develops the photoresist 150 so as to obtain the desired etch pattern in substrate 160 upon etching. Intentionally defocusing the pattern image on the photoresist, by using optical elements, smoothes the errors associated with substrate etching.

The optical device 180 can be any optical device, which provides the desired amount of defocusing with respect to the positions of the stepper and photoresist. For example a simple convex lens or frenel lens would suffice. However, more complicated telescopic type configurations and more than one optical device may also be used. Hence, discussion herein should not be interpreted to limit the type of optical device(s) used in a particular embodiment.

Moving the stepper beyond its defocusing range is an embodiment of the present invention, as discussed above. However, in order to revert back to standard practices when desired some method of focusing the pattern image back to the photoresist is needed. This can be accomplished, as discussed above, by an optical device placed between the stepper and a mask. An optical device can also be used between the mask and the photoresist when the stepper is not moved but defocusing is desired beyond the stepper's defocusing range. Another embodiment of the present invention provides a defocusing capability beyond a stepper's focusing range by placing an optical device between the mask and the photoresist layer. For example a thin (e.g., 250 μm-1000 μm) clear (e.g., SiO₂, quartz) cover plate can be placed above the photoresist layer to alter the pattern image focusing characteristics. An optical device or element placed between the mask and the photoresist layer can change the focusing characteristics of the illuminated light resulting in a pattern image on a plane not coincidental with the photoresist layer. For example an optically transparent thin plate can be placed above the photoresist layer to vary the refractive (focusing) characteristics of the illuminating light, resulting in a pattern image that can be defocused on the photoresist layer.

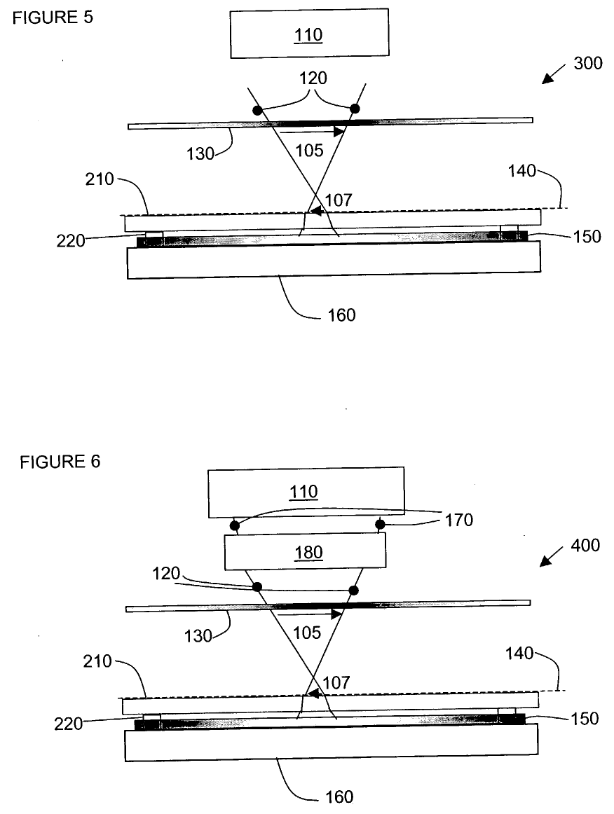

FIG. 5 illustrates a device/method 300 using an embodiment of the present invention that uses an optical device placed between the mask and photoresist layer to vary the focusing characteristics of the pattern image. An illumination device 110 emits focusing light, defined by conical extent 120. A reduced pattern image 107 is focused at a plane 140 away from the photoresist layer 150. The plane 140 corresponds to the location of a thin (e.g., 250 μm-1000 μm, and the like) clear (e.g., SiO₂, quartz, and the like) cover plate 210 above the photoresist layer 150 and substrate 160. The cover plate 210 sits on a stand 220, which separates the cover plate 210 from the photoresist layer 150. The photoresist 150 is patterned and developed by the illumination light 120 passing through the grayscale mask 130 and it is the mask (in the present example the grayscale mask) that can contain the errors seeking to be addressed by the present invention. The mask 130 contains a pattern that is imparted to the light passing through the mask 130 forming a pattern image 105. The pattern image 105 is reduced and focused at a focal plane 140 on or in the cover plate 210. The pattern image on the photoresist is defocused an intentional amount due to the cover plate 210.

The defocused image exposes the photoresist 150 forming a defocused pattern in the photoresist which can be used to obtain the desired etch pattern in substrate 160 upon etching. The stand 220 spaces the plate 210 a desired distance from the photoresist 150 and can be formed of any material, such as Si, SiO₂, and the like, suited to the particular needs at the time of operation, and can be attached to the cover plate 210, or attached to the substrate 160, or be independent such as a ring or peg that then sits on the substrate. Hence, the discussion herein should not be interpreted to limit the material or attachment of the stand. The cover plate is a particular example of an optical device. The cover plate can be a birefringent crystal, a multi-lens optical device situated to modify the focus of the illuminating light, or have varying planar optical properties such as a microlens array. Therefore, the discussion herein should not be interpreted to limit the characteristics of element 210 to a single optical element, material, or optical device.

In some situations it may be desirable to both defocus the general illumination beam and to provide varying focusing properties across the photoresist layer. An embodiment of the present invention combines an optical device placed between the stepper (illumination device) and the mask to generally defocus the pattern image incident on the photoresist layer, and a second optical device between the mask and the photoresist substrate that can have varying optical focusing characteristics parallel to the photoresist substrate.

FIG. 6 illustrates a device/method 400 using an embodiment of the present invention having an optical device 180 to vary the focusing characteristics of the light emitted from the stepper 110 and an optical device to vary the optical focusing properties across a direction parallel to the photoresist layer 150. Light, defined by the conical extents 170, is emitted from the illumination device 110 and is incident upon an optical device 180. The optical device 180 changes the focusing characteristics of the incident light. The transmitted light, defined by the conical extents 120, passes through a mask 130. A reduced pattern image 107 is focused at a focal plane 140 spaced away from the photoresist layer 150. The plane 140 corresponds to the location of a thin (e.g., 250 μm-1000 μm, etc. . . . ) clear (e.g., SiO₂, quartz, etc. . . . ) cover plate 210 above the photoresist layer 150 and substrate 160. The cover plate 210 sits on a stand 220, which separates the cover plate 210 from the photoresist layer 150. As previously mentioned, the stand can be part of the cover plate, part of the substrate 160, or a separate element such as a peg or ring.

The photoresist 150 is patterned and developed by the illumination light 120 passing through the grayscale mask 130 and it is the mask that can contain the errors seeking to be addressed by the present invention. The mask 130 contains a pattern that is imparted to the light passing through the mask 130 forming a pattern image 105. The pattern image 105 is reduced and focused on the focal plane 140 or a reduced image 107, in this case on or in the cover plate 210. The pattern image on the photoresist is defocused an intentional amount due to the cover plate 210 and the optical device 180.

As mentioned previously, intentional defocusing can be accomplished by optical elements before the mask 180 and/or after the mask 210 (e.g. coverplate). The defocused pattern image exposes the photoresist 150 forming a defocused pattern in the photoresist which can be used to obtain the desired etch pattern in substrate 160 upon etching. The cover plate is a particular example of an optical device. The cover plate could also be an optical element having anisotropic properties.

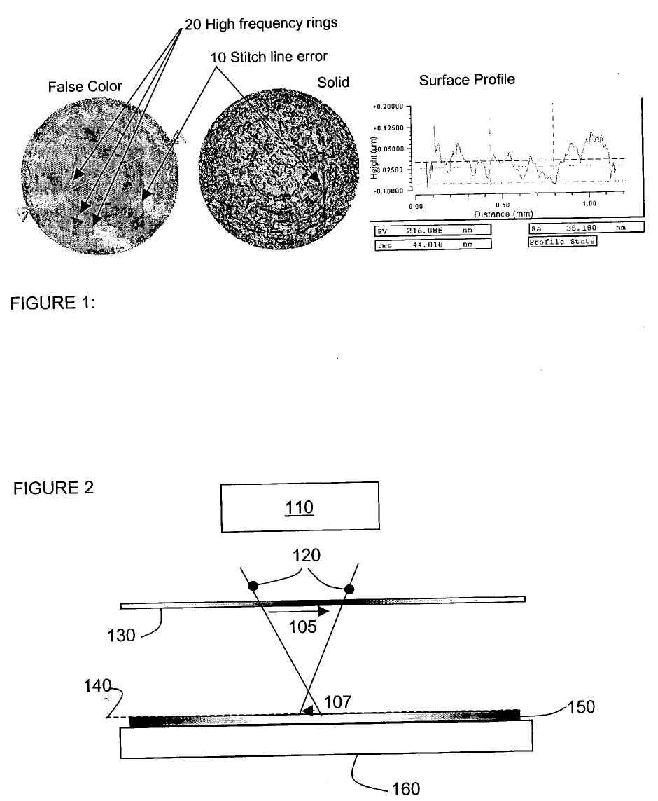

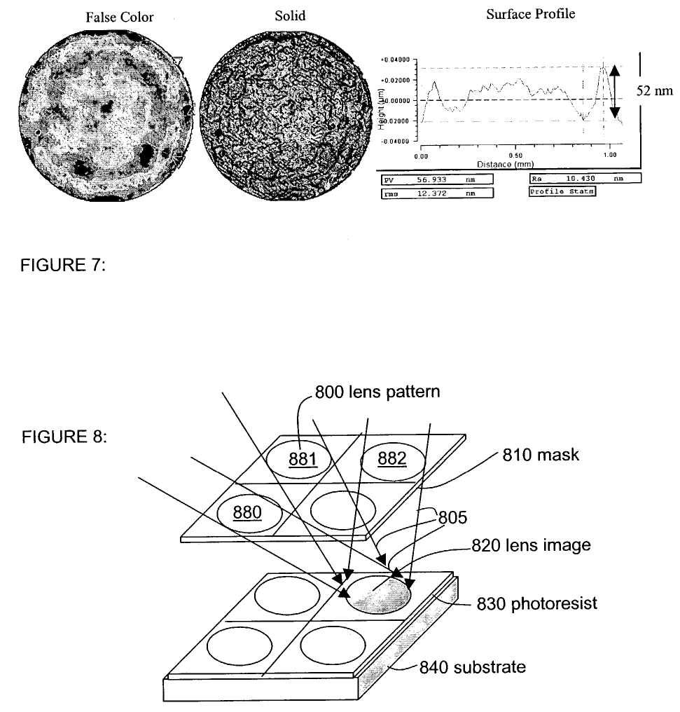

FIG. 7 illustrates the results on micro-lens etching using a device/method in accordance with the present invention shown in FIG. 4. Comparing FIG. 7 with FIG. 1 one can see that the associated errors are appreciably less in FIG. 7. In FIG. 7 the resultant lens has a height of 17.5 microns, a peak to valley roughness (difference) of <60 nm or 0.3% of the total height, a fourfold increase in accuracy over a the standard procedure produced lens of FIG. 1. The lens in FIG. 7 has a root mean squared (RMS) roughness of ˜12 nm or 0.07% of the total height; a three to fourfold increase in accuracy over the lens produced by the standard process.

FIG. 8 illustrates another embodiment of the present invention. When mass arrays of identical micro-lenses are etched there are errors associated with pattern variations across the mask, as described above. The present invention reduces pattern variational errors by using multiple exposures of each identical mask lens pattern to fully develop the image pattern of a single lens in a photoresist on a substrate. Hence a multiple amount of the lens patterns are used for each lens image exposed in the photoresist. For example FIG. 8 shows four lens patterns 800 formed in the mask 810. Multiple illuminations 805 of each lens patterns 800 contributes to the exposure and development of a lens image 820 in the photoresist 830, where the photoresist 830 is deposited on a substrate 840. In the example shown in FIG. 8 only three lens patterns 880, 881, and 882 are used to develop lens image 820. For example the exposure of lens pattern 880 could be ⅓^{rd} that needed to fully expose the photoresist in the pattern of the lens image 820. Successive exposures using different lens patterns, 881 and 882, results in a cumulative exposure large enough to fully develop the lens image 820 into the photoresist. However any number of predetermined exposures and lens patterns can be used to accumulate exposures forming a lens image and the discussion herein should not be interpreted to limit the number of exposures or the number of lens patterns used. The multiple exposures of different lens patterns 800 smoothes the overall (fully exposed) resultant lens image 820 so as to reduce the third type of error mentioned above having to do with variations across the mask.

Many variations of the processes and apparatus described herein can be made by one of ordinary skill in the art and any such variations should be deemed obvious with respect to the present invention and considered to lie within the scope of the present invention.

We claim:

1. An apparatus comprising:
an optical device positioned above a photoresist layer deposited on a substrate, wherein illumination of the photoresist through said optical device, where the illumination has passed through a mask, results in a pattern image on said photoresist layer that is defocused an intentional amount, the pattern image exposing the photoresist, minimizing photoresist exposure errors.

2. The apparatus according to claim 1, further comprising:
a stand, wherein said stand extends from the substrate above the photoresist layer and wherein said optical device is attached to said stand.

3. The apparatus according to claim 1, wherein said optical device is a thin, optically transparent, plate.

4. The apparatus according to claim 1, wherein said optical device is a birefringent crystal.

5. The apparatus according to claim 1, wherein said optical device is a thin, optically transparent, plate having anisotropic optical properties.

6. The apparatus according to claim 2, wherein said stand is part of said substrate.

7. The apparatus according to claim 2, wherein said stand is part of said optical device and rests upon said substrate.

8. An apparatus comprising:
an illumination device, at a focused position, having a range of defocus; and
a photoresist layer deposited on a substrate, that is illuminated by a light passing through a mask resulting in patterning and exposure of said photoresist, and where the pattern image on said photoresist is defocused an intentional amount, the pattern image exposing the photoresist, minimizing errors in the exposed photoresist.

9. The apparatus according to claim 8, wherein the mask is a grayscale mask.

10. The apparatus according to claim 8, wherein defocusing is caused by moving the illumination device with respect to the top of the photoresist layer so that a pattern image on said photoresist layer is unfocused a predetermined amount at the top of the photoresist layer, so that photoresist exposure errors are minimized.

11. A method of decreasing errors associated with etching substrates comprising:
providing an illumination device, at a focused position, having a range of defocus, where said illumination device illuminates a mask resulting in a focused pattern image on or in a photoresist layer deposited on a substrate; and
intentionally defocusing said pattern image on or in a photoresist an intentional amount to minimize etching errors.

12. The method according to claim 11, wherein the defocusing is accomplished by positioning an optical device above a photoresist layer, wherein illumination passing through said optical device results in a pattern image on said photoresist layer that is defocused an intentional amount.

13. The method according to claim 11, wherein the defocusing is accomplished by intentionally moving said illumination device a distance greater than the range of defocus.

14. The method according to claim 11, wherein the defocusing is accomplished by intentionally defocusing said illumination device an amount greater than the thickness of said photoresist layer so that the focused said pattern image is moved away from a predetermined standard focusing position.

15. A micro-lens formed from a process comprising:
providing a grayscale mask, wherein said grayscale mask contains a pattern to be etched in a substrate, where illumination light passing through said mask results in a pattern image on or in a photoresist layer deposited on said substrate;
defocusing the pattern image on the photoresist;
illuminating, patterning, and developing said photoresist layer with the defocused said pattern image; and
etching said substrate, wherein said etching uses said photoresist layer and results in a curved surface etched into said substrate.

16. The micro-lens formed according to claim 15, wherein the step of defocusing is accomplished by positioning an optical device above said photoresist layer, wherein said optical device results in said pattern image on said photoresist layer that is defocused an intentional amount.

17. An apparatus comprising:
a mask, wherein said mask contains a pattern to be etched in a substrate, where illumination light passing through said mask results in a pattern image on or in a photoresist layer deposited on said substrate; and
a first optical device positioned above said photoresist layer; and
a second optical device positioned between said mask and the source of said illumination light, wherein said first and second optical devices result in a said pattern image on said photoresist layer that is defocused an intentional amount, to minimize etching errors.

18. An apparatus according to claim 17, wherein said first and/or second optical device is(are) thin, optically transparent, plate(s).

19. An apparatus according to claim 17, wherein said first and/or second optical device is(are), birefringent crystal(s).

20. A method of decreasing errors associated with etching arrays of identical patterns in substrates comprising:
providing an illumination device, at a focused position, having a range of defocus; and
multiple illuminating a mask containing multiple patterns, resulting in focused images on or in a photoresist layer deposited on a substrate, where each of the focused images results from multiple exposures of a plurality of the patterns.
